(19) United States
(12) Patent Application Publication
(10) Pub. No.: US 2025/0334879 A1
(43) Pub. Date: Oct. 30, 2025

(54) PHOTOSENSITIVE EPOXY RESIN COMPOSITION, LIQUID DISCHARGE HEAD, LIQUID DISCHARGE DEVICE, AND SURFACE TREATMENT METHOD

(71) Applicant: CANON KABUSHIKI KAISHA, Tokyo (JP)

(72) Inventors: HARUKA YAMAJI, Tokyo (JP); MIHO ISHII, Kanagawa (JP); ERIKA KOBATAKE, Kanagawa (JP)

(21) Appl. No.: 19/182,932

(22) Filed: Apr. 18, 2025

(30) Foreign Application Priority Data
Apr. 25, 2024 (JP) 2024-071585
Apr. 14, 2025 (JP) 2025-066318

(51) Int. Cl. G03F 7/038; B41J 2/14; B41J 2/16; C09D 5/16; C09D 7/65; C09D 163/00; G03F 7/004; G03F 7/16

(52) U.S. Cl. CPC G03F 7/038; B41J 2/1433; B41J 2/162; B41J 2/1631; C09D 5/1637; C09D 5/1656; C09D 7/65; C09D 163/00; G03F 7/0045; G03F 7/168

(57) ABSTRACT

A photosensitive epoxy resin composition, comprising at least: (A) an epoxy resin comprising two or more epoxy groups in one molecule; (B) a cationic polymerization catalyst; (C) a silicone compound comprising one or more alkylsiloxane groups in one molecule; and (D) an alcohol or phenol compound comprising a long chain alkyl group having 9 to 18 carbon atoms.

### BACKGROUND OF THE INVENTION

### Field of the Invention

The present disclosure relates to a resin composition that enables a surface treatment that imparts water-repellent and ink-repellent characteristics, particularly, a photosensitive epoxy resin composition capable of forming a coating film in a pattern by ultraviolet irradiation. That is, the present disclosure relates to a photosensitive epoxy resin composition, a surface treatment method in which the photosensitive epoxy resin composition is used, and a liquid discharge head and a liquid discharge device that are surface-treated with the photosensitive epoxy resin composition.

### Description of the Related Art

In a variety of fields, methods for obtaining water resistance and ink repellency by applying a water-repellent coating material to the surface of a base material of a member that requires those characteristics are generally known, and resin materials and coating materials used therein have been developed. For example, fluorine-based coating materials having a fluoroolefin or a perfluoro group are extremely stable both thermally and chemically, are excellent in terms of weather resistance, water resistance, chemical resistance, and solvent resistance, furthermore, are also excellent in terms of mold releasability, friction resistance, and water repellency, and are in wide use in a variety of applications.

Examples of the member that requires water resistance and ink repellency include inkjet type recording heads. A liquid discharge head is used in a liquid discharge device such as an inkjet recording device, and has a photosensitive resin layer that forms a discharge port and a flow path and a substrate. The photosensitive resin layer that forms the discharge port and the flow path is provided on the substrate. A supply port that supplies a liquid to the flow path is formed on the substrate. The surface of the substrate on a side where the flow path and the discharge port are provided has an energy generating element. The liquid is supplied from the supply port to the flow path, is supplied with energy from the energy generating element, is discharged from the liquid discharge port, and is landed on a recording medium such as paper.

In this liquid discharge head, the surface state of the discharge port-forming member has a large influence on the liquid discharge performance. Therefore, a liquid-repellent layer is formed on the surface of the discharge port-forming member, thereby trying to suppress adhesion of the liquid and keep the surface state uniform.

As such a liquid-repellent layer, a liquid-repellent layer made of a photosensitive epoxy resin composition comprising an alkylsiloxane-comprising epoxy resin, as described in Japanese Patent Application Publication No. 2003-020323, has been disclosed.

### SUMMARY OF THE INVENTION

Incidentally, requirements for the performance of the above-described liquid-repellent layer have become extremely high along with the rapid improvement in recent years of the performance of inkjet printers. That is, in an inkjet head, along with the progress of nozzle miniaturization and provision of multiple nozzles, high-level patterning properties (for example, excellent optical workability) are required even for the liquid-repellent layer. In addition, examples of basic characteristics that such a water-repellent film should have include adhesion to a base material and ink resistance (for example, water repellency or adhesion that is not significantly affected by contact with ink).

Furthermore, for ink itself, a variety of attempts have been made to improve the performance thereof, such as the use of a polar solvent and adjustment of increasing the pH. In order to prevent deterioration of the water repellency or damage to the adhesion to the base material due to contact with such ink, the liquid-repellent layer has been required to have favorable ink resistance (for example, alkali resistance and hydrolysis resistance). However, it is not easy to develop a material capable of satisfying the above-described high-level micro-workability while meeting these requirements.

In the case of a liquid-repellent layer for which the photosensitive epoxy resin composition comprising an alkylsiloxane-comprising epoxy resin as disclosed in Japanese Patent Application Publication No. 2003-020323 is used, due to the low compatibility between the siloxane component and the epoxy component, there are cases where the patterning properties are not sufficient to form miniaturized nozzles described above and a desired shape cannot be formed. Furthermore, in the case of using the above-described ink having improved performance, there are cases where the film-forming property of the liquid-repellent layer or the adhesion to applied members is impaired, the liquid-repellent layer peels off, and the water repellency is lost.

According to at least one aspect of the present disclosure, there is provided a photosensitive epoxy resin composition suitable as a water repellent or a water-repellent coating material that is applied to locations where there is an opportunity of contact with a solution or substance containing a component that impairs the film-forming property or adhesion of the water repellent, such as ink. Specifically, there is provided a photosensitive epoxy resin composition that is excellent in terms of patterning properties and water repellency and can be surface-modified to maintain the same surface state at all times.

In addition, a surface treatment of a base material with such a photosensitive epoxy resin composition makes it possible to maintain the nozzle surface in the same surface state at all times and makes it possible to suppress the attachment of ink to the surface of a print head even when in contact with a recording liquid for a long period of time. As a result, there are provided a liquid discharge head and a liquid discharge device that have favorable dot landing accuracy and are capable of relentlessly maintaining the printing quality for a long period of time.

According to at least one aspect of the present disclosure, there is provided a photosensitive epoxy resin composition, comprising at least:
(A) an epoxy resin comprising two or more epoxy groups in one molecule;
(B) a cationic polymerization catalyst;
(C) a silicone compound comprising one or more alkylsiloxane groups in one molecule; and
(D) an alcohol or phenol compound comprising a long chain alkyl group having 9 to 18 carbon atoms.

According to another aspect of the present disclosure, there is provided a surface treatment method comprising in order:
a first step of applying the above-described photosensitive epoxy resin composition to a base material, and drying the photosensitive epoxy resin composition to form a coating film;
a second step of irradiating a surface of the base material, on which the coating film has been formed, with an active energy ray in a pattern through a mask; and
a third step of dissolving and removing an uncured photosensitive epoxy resin composition present in a part not irradiated with the active energy ray.

According to another aspect of the present disclosure, there is provided a liquid discharge head, comprising:
a discharge port that discharges a recording liquid,
wherein at least an opening portion of the discharge port is coated with a cured product of the above-described photosensitive epoxy resin composition.

According to at least one aspect of the present disclosure, there are provided a photosensitive epoxy resin composition that is excellent in terms of patterning properties and water repellency, and a surface treatment method in which the photosensitive epoxy resin composition is used. In addition, according to at least one aspect of the present disclosure, there are provided a liquid discharge head and a liquid discharge device that are surface-treated with the above-described photosensitive epoxy resin composition and are capable of relentlessly maintaining the printing quality for a long period of time.

Further features of the present invention will become apparent from the following description of exemplary embodiments with reference to the attached drawings.

### BRIEF DESCRIPTION OF THE DRAWINGS

FIG. 1 is a main cross-sectional view of a configuration example of a liquid discharge head of the present embodiment;

FIG. 2 is a perspective view of a main part of the liquid discharge head;

FIG. 3 is a view showing an example of a liquid discharge device into which the liquid discharge head has been incorporated; and

FIGS. 4A to 4E are views showing production steps of a liquid discharge head in Examples.

### DESCRIPTION OF THE EMBODIMENTS

In the present disclosure the notations “from XX to YY” and “XX to YY” representing a numerical value range signify, unless otherwise specified, a numerical value range that includes the lower limit and the upper limit of the range, as endpoints. In a case where numerical value ranges are described in stages, the upper limits and the lower limits of the respective numerical value ranges can be combined arbitrarily.

In addition, in the present disclosure, for instance, a wording such as “at least one selected from the group consisting of XX, YY and ZZ” encompasses XX, YY and ZZ, a combination of XX and YY, a combination of XX and ZZ, a combination of YY and ZZ, and a combination of XX, YY and ZZ.

In an inkjet type recording head in which ink is discharged as small droplets from a discharge port and is attached to paper or the like to perform recording or the formation of an image, the discharge port desirably has the following performance.
(1) Residual ink in an ink pillar that has been turned into liquid drops is rapidly stored again in a nozzle
(2) Ink drops attached to the surface are easily swept out by a cleaning operation
(3) The ink drops attached to the surface have excellent scratch resistance in the cleaning operation and paper transportation
(4) Upon the formation of liquid drops and ink refills that are repeated, a meniscus is formed at the nozzle surface position
(5) The normal direction to the meniscus is the discharge direction
(6) The discharge port has interfacial tension, that is, a contact angle, large enough to form a meniscus even for ink having a low surface tension or in a low negative pressure state

The reason for a variety of these performances being required for the discharge port is that in the liquid discharge head, attachment of a recording liquid such as ink to the vicinity of the discharge port has a direct relationship with the printing performance since in such a case, the discharge (flying) direction of liquid drops that are discharged from the discharge port deviates and high accuracy printing becomes impossible. With regard to this, there is known a method in which a water-repellent treatment is performed on the surface on which the discharge port has been formed in order to prevent attachment of liquid to the vicinity of the discharge port which causes such a deviation of the discharge direction.

Examples of a method for the liquid-repellent treatment include methods in which a liquid-repellent layer made of a photosensitive epoxy resin composition comprising an alkylsiloxane-comprising epoxy resin is formed as described in Japanese Patent Application Publication No. 2003-020323. However, in the case of a liquid-repellent layer for which a conventional photosensitive epoxy resin composition comprising an alkylsiloxane-comprising epoxy resin is used, due to the low compatibility between the siloxane component and the epoxy component, there are cases where the patterning properties are not sufficient to form miniaturized nozzles as described above and a desired shape cannot be formed. Furthermore, in the case of using ink for which a polar solvent is used or the pH is adjusted to a high value for performance improvement, there are cases where the film-forming property of the liquid-repellent layer or the adhesion to applied members is impaired, the liquid-repellent layer peels off, and the water repellency is lost.

Regarding the above-described problems, the present inventors found that a photosensitive epoxy resin composition comprising a specific component makes it possible to satisfy both high-level patterning properties and water repellency. In addition, it was found that a liquid discharge head capable of maintaining the printing quality favorably even in long-term use can be provided by performing a surface treatment of a discharge port with the photosensitive epoxy resin composition.

A photosensitive epoxy resin composition of the present disclosure is an epoxy resin-based composition and thus has excellent adhesion to a variety of members, can be cured even at relatively low temperatures, and is capable of providing a cured product having excellent physical properties. In addition, the photosensitive epoxy resin composition comprises a silicone compound comprising an alkylsiloxane group, and is thereby capable of providing a cured product having excellent water repellency. Furthermore, there is provided a photosensitive epoxy resin composition that comprises an alcohol or phenol compound comprising a long chain alkyl group having 9 to 18 carbon atoms as a compatibilizer and is thereby capable of significantly improving compatibility between the epoxy resin and the silicone compound and capable of satisfying both patterning properties and water repellency.

The photosensitive epoxy resin composition of the present disclosure is useful as a water repellent or a water-repellent coating material that is applied to locations where there is an opportunity of contact with a solution or substance comprising a component that impairs the adhesion of the water repellent, such as ink. Particularly, the photosensitive epoxy resin composition is suitable for water- and ink-repellent treatments on the surfaces of discharge ports in inkjet recording heads.

Hereinafter, the present disclosure will be described in detail. In the following description, the photosensitive epoxy resin composition may be simply referred to as the photosensitive resin composition or the resin composition.

The photosensitive epoxy resin composition comprises at least (A) an epoxy resin comprising two or more epoxy groups in one molecule, (B) a cationic polymerization catalyst, (C) a silicone compound comprising one or more alkylsiloxane groups in one molecule, and (D) an alcohol or phenol compound comprising a long chain alkyl group having 9 to 18 carbon atoms.

### (A) Epoxy Resin

The epoxy resin has two or more epoxy groups in one molecule. The epoxy resin is bifunctional or higher, whereby a curing reaction progresses. The photosensitive resin composition comprises the epoxy resin and thereby three-dimensionally cross-links upon curing and makes it possible to obtain a cured product having desired characteristics.

Examples of the epoxy resin comprising two or more epoxy groups in one molecule include the followings.

Examples thereof include cationic polymerization type epoxy resins such as polyfunctional epoxy resins, such as epoxy resins having a bisphenol skeleton such as bisphenol A type or F type epoxy resins, epoxy resins having a phenol novolac skeleton such as phenol novolac type epoxy resins, epoxy resins having a cresol novolac skeleton such as cresol novolac type epoxy resin, epoxy resins having a norbornene skeleton, epoxy resins having a terpene skeleton, epoxy resins having a dicyclopentadiene skeleton, and epoxy resins having an oxycyclohexane skeleton. One or a combination of two or more thereof can be used.

The photosensitive epoxy resin composition preferably comprises a cationic polymerization type epoxy resin in consideration of reactivity, resolution, furthermore, adhesion to a variety of members, or physical properties as a cured product. Furthermore, addition of a cationic polymerization catalyst makes it possible to prepare a photocationic photosensitive epoxy resin composition.

The epoxy resin comprising two or more epoxy groups in one molecule is not particularly limited, and known epoxy resins can be used. Examples of commercially available bifunctional epoxy resins include “jER1004”, “jER1007”, “jER1009”, “jER1010”, “jER1256” (trade names) manufactured by Mitsubishi Chemical Corporation, “EPICLON 4050”, “EPICLON 7050” (trade names) manufactured by DIC Corporation, and the like.

The epoxy resin preferably comprises an epoxy resin comprising a tri- or higher-functional epoxy group in one molecule

The epoxy resin comprising a tri- or higher functional epoxy group in one molecule is not particularly limited, and known epoxy resins can be used. Examples of commercially available tri- or higher functional epoxy resins include “CELLOXIDE 2021”, “GT-300 series”, “GT-400 series”, “EHPE-3150” (trade names) manufactured by Daicel Corporation, “jER1031S”, “157S70” (trade names) manufactured by Mitsubishi Chemical Corporation, “EPICLON N-695”, “EPICLON N-865”, “EPICLON HP-6000”, “EPICLON HP-4710”, “EPICLON HP-7200 series”, and “EPICLON EXA-4816” (trade name) manufactured by DIC Corporation.

The content of the epoxy resin in the photosensitive epoxy resin composition is not particularly limited, but is, for example, preferably 50 to 90 parts by mass, more preferably 55 to 85 parts by mass, and still more preferably 60 to 80 parts by mass relative to the total mass of the photosensitive epoxy resin composition.

From the viewpoint of further improving the patterning properties of the resin composition, it is more preferable to use an epoxy resin highly compatible with a silicone compound, which will be described below, as the epoxy resin having a tri- or higher-functional epoxy group. In the case of using an epoxy resin poorly compatible with a silicone compound, the amount of the component (D), which will be described below, added as a compatibilizer increases, whereby the patterning properties of the resin composition can be improved.

### (B) Cationic Polymerization Catalyst

The photosensitive epoxy resin composition comprises a cationic polymerization catalyst. The cationic polymerization catalyst is a catalyst for curing the epoxy resin.

The cationic polymerization catalyst can be appropriately selected from substances known as curing agents for epoxy resins. The epoxy resin composition can be polymerized by adding aromatic and aliphatic amines and acid anhydrides and heating and curing them.

In particular, from the viewpoint of more suitably performing the surface modification of the base material, it is preferable to use, for example, the following substances as the cationic polymerization catalyst.

For example, a sulfonic acid compound, a diazomethane compound, a sulfonium salt compound, an iodonium salt compound, a disulfone-based compound, or the like is preferable. Examples of commercially available products include “OPTOMER SP-170”, “OPTOMER SP-172”, “SP-150”, (trade names) manufactured by ADEKA Corporation, “BBI-103”, “BBI-102” (trade names) manufactured by Midori Kagaku Co., Ltd., “IBPF”, “IBCF”, “TS-01”, “TS-91” (trade names) manufactured by Sanwa Chemical Co., Ltd., “CPI-210”, “CPI-300”, “CPI-410” (trade names) manufactured by San-Apro Ltd., “Irgacure 290” (trade name) manufactured by BASF Japan Ltd., and the like.

The content of the cationic polymerization catalyst in the photosensitive epoxy resin composition is not particularly limited, but is, for example, preferably 1 to 20 parts by mass and more preferably 5 to 10 parts by mass relative to the total mass of the photosensitive epoxy resin composition.

The use of the cationic polymerization catalyst allows high reactivity to be exhibited with respect to an onium salt of a Lewis acid that is activated by an active energy ray, allowing particularly low-temperature curing and makes it possible to selectively perform the surface treatment by a photolithography method. In addition, surface modification can also be suitably performed on a base material that is difficult to maintain at high temperatures.

### (C) Silicone Compound

The photosensitive epoxy resin composition comprises a silicone compound comprising one or more alkylsiloxane groups in one molecule. The silicone compound comprising an alkylsiloxane group acts as a water-repellent component.

The silicone compound comprising an alkylsiloxane group can be appropriately selected from a variety of organic modified silicone compounds. Since the photosensitive epoxy resin composition is an epoxy-based resin composition, it is preferable to use an epoxy-modified silicone having an epoxy group introduced into a silicone compound. When an epoxy group is introduced into the silicone compound, the silicone compound also reacts along with the progress of curing of the epoxy resin, and strong water-repellent durability can be obtained.

The epoxy-modified silicone is not particularly limited, and known silicone can be used. For example, both-terminal, single-terminal, or side-chain epoxy-modified silicone can be used. Examples of commercially available epoxy-modified silicone include “BY 16-839”, “SF 8411”, “SF-8413”, “SF-8421” (trade names) manufactured by Dow Corning Toray Co., Ltd., “X-22-163”, “KF-105”, “X-22-163A”, “X-22-163B”, “X-22-163C”, “X-22-169AS”, “X-22-169B”, “X-22-173BX”, “X-22-173DX”, and “X-22-9002” (trade names) manufactured by Shin-Etsu Chemical Co., Ltd.

It is more preferable that a both-terminal epoxy-modified silicone is used, whereby a photosensitive resin composition that satisfies both patterning properties and water repellency can be provided. That is, the silicone compound is preferably a both-terminal epoxy-modified silicone compound in which both ends of one molecule are modified to epoxy groups.

When epoxy groups are introduced into both ends of one molecule, it is possible to efficiently orient water-repellent groups (methyl groups) on the surface compared with side chain modification. In addition, since it is believed that the water-repellent group on the outermost surface of the cured product is unlikely to rotate internally compared with single-terminal type, the both-terminal epoxy-modified silicone compound is preferably used.

The both-terminal epoxy-modified silicone compound is not particularly limited, and known compounds can be used. Examples of commercially available products thereof include “X-22-163”, “KF-105”, “X-22-163A”, “X-22-163B”, “X-22-163C” manufactured by Shin-Etsu Chemical Co., Ltd. and the like.

Among the both-terminal epoxy-modified silicone compounds, it is more preferable to use a compound having an epoxy group functional group equivalent of 150 or more and 3000 or less. In addition, a compound having an epoxy group functional group equivalent of 490 or more and 1800 or less is more preferable.

It is believed that when the epoxy group functional group equivalent weight is 150 or more, the reactivity of the epoxy groups at the terminals is not too high, and the water-repellent groups are likely to be oriented on the surface during curing. On the other hand, when the epoxy group functional group equivalent is 3000 or less, the silicone structure of the main chain is not too long and is unlikely to aggregate in the epoxy resin, and it is thus believed that the patterning properties are likely to be improved.

The content of the silicone compound relative to 100 parts by mass of the epoxy resin is preferably 0.5 parts by mass or more and 10 parts by mass or less. When the content is 0.5 parts by mass or more, since the water-repellent groups are sufficiently present in the resin, it becomes easy to improve the water repellency. In addition, when the content is 10 parts by mass or less, it becomes easy to further improve the patterning properties.

The content of the silicone compound in the photosensitive epoxy resin composition is not particularly limited, but is, for example, preferably 0.1 to 20 parts by mass and more preferably 0.2 to 10 parts by mass relative to the total mass of the photosensitive epoxy resin composition.

### (D) Alcohol or Phenol Compound

The photosensitive epoxy resin composition comprises an alcohol or phenol compound comprising a long chain alkyl group having 9 to 18 carbon atoms as a compatibilizer.

The alcohol or phenol compound acts as a compatibilizer for an alcohol group or phenyl group having hydrophilic characteristics and a long chain alkyl group having hydrophobic (lipophilic) characteristics. When the photosensitive epoxy resin composition comprises the above-described alcohol or phenol compound, improvement in the compatibility between the epoxy resin and the silicone compound is possible. Furthermore, the use of the alcohol or phenol compound in which the long chain alkyl group has 9 to 18 carbon atoms makes it possible to provide a resin composition having patterning properties and water repellency.

When the alcohol or phenol compound having nine or more carbon atoms in the alkyl group is used, the boiling point becomes high, and the composition is unlikely to volatilize during curing, and it is thus possible to further improve the patterning properties of the photosensitive epoxy resin composition. In addition, when the alcohol or phenol compound having 18 or less carbon atoms is used, the chain length is not too long, and it is possible to sufficiently obtain an effect as the compatibilizer.

Examples of the alcohol or phenol compound comprising a long chain alkyl group having 9 to 18 carbon atoms include lauryl alcohol (C12), myristyl alcohol (C14), cetanol (C16), stearyl alcohol (C18), p-nonylphenol (having nine carbon atoms in an alkyl group in a side chain), and the like.

In addition, in order to further improve the patterning properties and the water repellency, it is more preferable to use lauryl alcohol, myristyl alcohol, and stearyl alcohol as the compatibilizer. That is, the alcohol or phenol compound is preferably at least one selected from the group consisting of lauryl alcohol, myristyl alcohol, and stearyl alcohol.

The total content of the alcohol or the phenol compound relative to 100 parts by mass of the epoxy resin is preferably 10 parts by mass or more and 50 parts by mass or less. The content is more preferably 20 parts by mass or more and 40 parts by mass or less and still more preferably 25 parts by mass or more and 35 parts by mass or less.

When the total content of the alcohol or the phenol compound is 10 parts by mass or more, the alcohol or the phenol compound appropriately acts as a compatibilizer, makes segregation unlikely to occur in the epoxy resin or the silicone compound, and is capable of further improving the water repellency. In addition, when the total content of the alcohol or the phenol compound is 50 parts by mass or less, remaining of the alcohol or the phenol compound after curing is suppressed, and it is possible to further improve the patterning properties.

In a case where the total content of the alcohol or phenol compound exceeds 50 parts by mass, the patterning properties are likely to deteriorate when an epoxy resin that is poorly compatible with the silicone compound is used as the component (A). That is, when the total content of the alcohol or the phenol compound is set within the above-described range, a resin composition having excellent patterning properties can be obtained even in a case where an epoxy resin that is poorly compatible with the silicone compound is used.

The content of the alcohol or the phenol compound in the photosensitive epoxy resin composition is not particularly limited, but is, for example, preferably 3 to 40 parts by mass and more preferably 5 to 30 parts by mass relative to the total mass of the photosensitive epoxy resin composition.

The photosensitive epoxy resin composition may comprise components other than the above-described components (A) to (D). For example, a silane coupling agent or the like can also be added to further improve adhesion performance. Examples of commercially available silane coupling agents include “A-187” (trade name) manufactured by Momentive Performance Materials.

The photosensitive resin composition can be used as a water repellent or a water-repellent coating material that is applied to locations where there is an opportunity of contact with a solution or substance comprising a component that impairs the adhesion of the water repellent, such as ink. In addition, it is possible to suitably perform water- and ink-repellent treatments on the surfaces of discharge ports in liquid discharge heads using the photosensitive resin composition.

### Surface Treatment Method

Hereinafter, a method for performing a surface treatment using the photosensitive epoxy resin composition will be described. The photosensitive epoxy resin composition can be used for a surface treatment of, for example, a discharge port of a liquid discharge head having the discharge port that discharges a recording liquid.

A first surface treatment method includes a first step of forming a coating film by applying and drying the photosensitive epoxy resin composition on a base material, a second step of irradiating the surface of the base material on which the coating film has formed with an active energy ray in a pattern through a mask, and a third step of dissolving and removing the uncured photosensitive epoxy resin composition present in a part not irradiated with the active energy ray in the second step.

In addition, it is desirable to further include a fourth step of performing a heat treatment or irradiation with an active energy ray after the third step to complete the reaction of the photosensitive epoxy resin composition.

Hereinafter, each step will be described in detail.

### First Step

In the first step, the base material is not particularly limited. As the base material, for example, a silicon wafer substrate or the like can be used. The base material may be a base material provided with a discharge energy generating element of a liquid discharge head.

The photosensitive epoxy resin composition is used in a state of being dissolved in an organic solvent. As the organic solvent, known solvents such as aromatic, aliphatic hydrocarbon-based, ester-based, ether-based, and fluorine-based solvents can be used.

For example, propylene glycol monomethyl ether acetate (PGMEA) and the like can be used as the organic solvent. The content of the photosensitive epoxy resin composition in the solution is not particularly limited, but is, for example, preferably 10 to 50 mass % and more preferably 30 to 40 mass % relative to the total mass of the solution.

A method for applying the photosensitive epoxy resin composition to the base material is not particularly limited, and known methods can be used. For example, in a case where the film thickness of the photosensitive epoxy resin composition applied is as small as several micrometers, the photosensitive epoxy resin composition can be applied using a normal precision application device such as a roll coater, a spin coater, or a spray coater.

The film thickness at the time of applying the photosensitive epoxy resin composition solution to the base material is not particularly limited, but is, for example, preferably 0.1 to 10 μm, more preferably 0.5 to 5 μm, and still more preferably 1 to 3 μm. In addition, the temperature or time at the time of drying the photosensitive epoxy resin composition solution applied to the base material can be adjusted as appropriate depending on the base material or the composition of the photosensitive epoxy resin composition. For example, it is preferable to dry the photosensitive epoxy resin composition solution at 100° C. to 200° C. for 5 to 30 minutes.

The applied photosensitive epoxy resin composition solution is dried, whereby a solvent is removed from the solution, and a coating film comprising the photosensitive epoxy resin composition is formed.

### Second Step

The second step is a step of irradiating the surface of the coating film formed in the first step with an active energy ray in a pattern through a mask. The irradiation through the mask makes the photosensitive resin composition only in a part irradiated with the active energy ray selectively cured and makes it possible to obtain a desired shape.

In the second step, a mask having a flow path pattern, which will be described below, formed therein is used. The material of the mask is not particularly limited, and a material that is generally used as photo masks can be used.

As the active energy ray, for example, an ultraviolet ray abundantly containing light having a wavelength of 250 to 480 nm can be used.

### Third Step

The third step is a step of dissolving and removing the uncured photosensitive resin composition present in the part not irradiated with the active energy ray in the second step by a development treatment using a developer.

As the developer, it is necessary to select a solvent suitable for the resin composition. As the developer, aromatic hydrocarbons, ketones, esters, glycol ethers, and the like, mixtures thereof, and the like can be used. For example, a solution such as methyl isobutyl ketone (MIBK) or NaOH can be used as the developer.

In the third step, a method for the development treatment is not particularly limited, and known methods can be used. For example, the uncured resin composition present in the part not irradiated with the active energy ray can be dissolved and removed by immersing the base material on which the pattern has been formed after the second step in the developer.

If necessary, the fourth step may be performed after the third step. In the fourth step, for example, a heating treatment is performed on the base material after the third step at a heating temperature of 100° C. to 200° C. Alternatively, the photosensitive resin composition may be further irradiated with an active energy ray such as an ultraviolet ray.

Examples of a second surface treatment method include methods in which the photosensitive epoxy resin composition is molded in a pattern by a method different from the first surface treatment method.

The second surface treatment method includes a first step of applying and drying the resin composition on the base material to form a coating film, a second step of performing a heat treatment or irradiation with an active energy ray on the entire surface of the base material on which the coating film has been formed and polymerizing and curing the entire surface of the photosensitive epoxy resin composition to obtain a cured product, and a third step of selectively irradiating the cured product with a collapsible active energy ray to mold the cured product into a pattern.

The second surface treatment method also preferably includes a fourth step of performing a heat treatment or irradiation with a polymerizable active energy ray after the second step or the third step to complete the curing reaction.

In the second method, the first step and the fourth step can be performed by the same method as in the first surface treatment method described above.

In the second step, the entire surface of the coating film formed in the first step is irradiated with heat or an active energy ray that promotes polymerization and cured. As the active energy ray that promotes the polymerization, an ultraviolet ray source abundantly containing light having a wavelength of 250 to 480 nm is used. In addition, the polymerization may be promoted by a heat treatment. For example, it is preferable to perform a heating treatment at a heating temperature of 100° C. to 200° C.

In the third step, a desired part of the cured product obtained in the second step is irradiated with a collapsible active energy ray so as to be selectively removed. As the collapsible active energy source, light having a wavelength of 210 nm or shorter, for example, an excimer laser, is used. A desired part of the cured product is selectively removed, whereby it is possible to mold the photosensitive epoxy resin composition in a desired pattern.

### Liquid Discharge Head

As an application in a liquid discharge head, the surface of a discharge port is treated using the above-described photosensitive epoxy resin composition by the above-described method, whereby a surface having excellent mold releasability that does not cause firm attachment of ink and is easily wiped off by a cleaning treatment is formed.

As described above, the surface treatment of the liquid discharge head can be performed by applying and curing the photosensitive epoxy resin composition on the surface of the liquid discharge head formed in advance. In addition, it is also possible to use a cured product obtained by curing the photosensitive epoxy resin composition in a pattern as the discharge port of the liquid discharge head.

The majority of cleaning mechanisms that are mounted in liquid discharge heads are wiping off with a rubber blade, sucking with a pump, idle discharging at a position outside recording paper, and the like. However, in any of these methods, when an ink pillar drawn out by the discharge pressure is converted into liquid drops, not all of the ink becomes liquid drops, and it is thus difficult to completely prevent the liquid droplets of extra ink from being attached to the vicinity of the discharge port. However, if the liquid droplets of the ink drop due to their own weights, are sucked again into the discharge port, or the like and are thereby easily eliminated, it can be believed that there are no influences on ink discharge any longer.

The surface treatment of the discharge port using the above-described photosensitive epoxy resin composition makes it possible to maintain the surface of the nozzle in the same surface state at all times and makes it possible to suppress the ink being attached to the surface of a print head even when the print head has been in contact with the recording liquid for a long period of time. As a result, it becomes possible to provide a liquid discharge head and a liquid discharge device that are capable of relentlessly maintaining the printing quality for a long period of time.

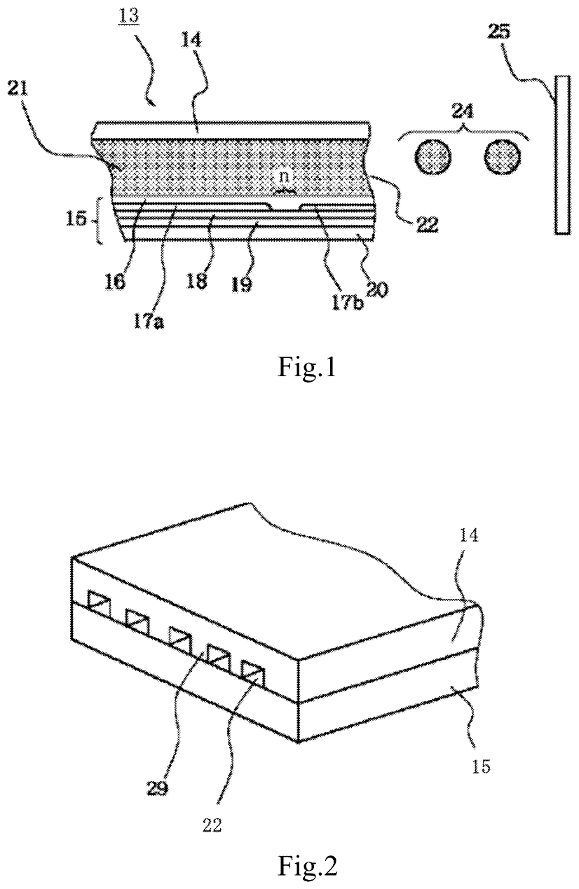

FIGS. 1 and 2 show a main part of an example of the configuration of a liquid discharge head to which the photosensitive epoxy resin composition can be applied. FIG. 1 is a cross-sectional view taken along a flow path of the liquid discharge head, and FIG. 2 is a perspective view.

A liquid discharge head 13 has a configuration in which a member 14 in which a cured product or the like of a resin composition has been molded in a desired pattern and made to form at least a flow path is laminated and joined onto a base body 15 on which a discharge energy generating element or the like has been arranged. As the resin composition, the above-described photosensitive epoxy resin composition can be used. Alternatively, a thermosetting resin composition and/or an active energy ray-curable resin composition may also be used as the resin composition, the above-described photosensitive epoxy resin composition may be applied onto the surface of the cured product, and a surface treatment may be performed thereon.

The base body 15 has a configuration in which a heat storage layer 19, a heat generating resistor layer 18 formed of a metal, electrodes 17a and 17b made of aluminum or the like, and a protective layer 16 are laminated in this order on a surface of a substrate 20 made of a material having favorable heat dissipation such as alumina. The discharge energy generating element formed in a part of the heat generating resistor layer 18 where the electrodes are not laminated (a part within a region indicated by n) is made to generate heat by conducting electricity to the electrodes 17a and 17b, and heat energy acts on a recording liquid 21 positioned above the heat generating resistor layer.

During recording, the recording liquid 21 is loaded up to discharge ports (orifices) 22 that are fine openings at the end portions of the flow paths in the member 14. When electricity is conducted to the electrodes 17a and 17b in this state according to a recording signal, the region indicated by n abruptly generates heat, bubbles are generated due to film boiling in the recording liquid 21 in contact with the region, the recording liquid 21 is discharged as small liquid drops 24 from the discharge ports 22 by the pressure of the bubbles, and fly toward a recording medium 25.

In the liquid discharge head, the cured product of the above-described photosensitive epoxy resin composition is applied as a water-repellent and ink-repellent agent to at least the opening portions of the discharge ports on a discharge surface 29 (a surface having the opening portions of the discharge ports), and liquid drops are attached to this surface to prevent the discharge direction of the liquid drops from deviating. That is, in the liquid discharge head, at least the opening portions of the discharge ports are coated with the cured product made of the photosensitive epoxy resin composition.

As described above, the discharge port may be formed using the cured product of the photosensitive epoxy resin composition. In addition, a surface treatment may be performed on the surface of the discharge port formed using a different resin composition by applying and curing the above-described photosensitive epoxy resin composition.

That is, a method for manufacturing the liquid discharge head may include a step of applying the above-described photosensitive epoxy resin composition to the surface of a face where the discharge ports have been formed and a step of curing the photosensitive epoxy resin composition by exposure and a heating treatment.

In addition, the method for manufacturing the liquid discharge head may include a step of performing a surface treatment by the above-described surface treatment method including the first step, the second step, and the third step on the base material provided with the discharge energy generating element of the liquid discharge head. In addition, the above-described surface treatment method may also include the above-described fourth step if necessary.

The cured product of the photosensitive epoxy resin composition does not only have excellent adhesion but also has water repellency or adhesion that is not impaired by an organic solvent, particularly, a polar organic solvent, even when the recording liquid (ink) comprises the organic solvent.

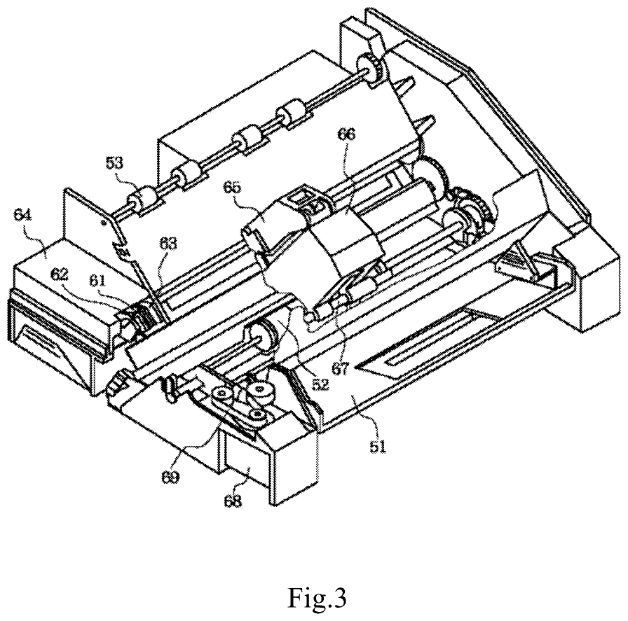

FIG. 3 shows an example of an inkjet recording device that is a liquid discharge device into which the liquid discharge head as shown in FIG. 2 has been incorporated. As the liquid discharge head of the liquid discharge device, it is possible to use the liquid discharge head on which a surface treatment has been performed with the above-described photosensitive epoxy resin composition.

In FIG. 3, reference numeral 61 denotes a blade as a wiping member, one end thereof is held by a blade holding member to act as a fixed end, and the blade has a cantilever form. The blade 61 is disposed at a position closer to a recording region than a recording head and, in the present example, is held in a form of protruding into the movement path of the recording head. Reference numeral 62 denotes a cap, and the cap is disposed at a home position adjacent to the blade 61, and is configured to move in a direction perpendicular to the movement direction of the recording head to abut on the discharge port and to perform capping. Furthermore, reference numeral 63 denotes an ink absorbing body provided adjacent to the blade 61, and is held in a form of protruding into the movement path of the recording head, like the blade 61. The blade 61, the cap 62, and the ink absorbing body 63 configure a discharge recovery portion 64, and the blade 61 and the ink absorbing body 63 remove moisture, dust, and the like from the ink discharge port surface.

Reference numeral 65 denotes a recording head that performs recording by an inkjet method, and has a configuration in which, for example, a recording liquid such as ink is discharged by heat energy as shown in FIG. 1 and FIG. 2. Reference numeral 66 denotes a carriage for moving the recording head 65 with the recording head 65 mounted thereon. The carriage 66 is slidably engaged with a guide shaft 67, and a part of the carriage 66 is connected (not shown) to a belt 69 that is driven by a motor 68. This makes it possible for the carriage 66 to move along the guide shaft 67, that is, move to the recording region by the recording head 65 and a region adjacent thereto.

Reference numeral 51 denotes a sheet feeding portion for inserting a recording medium, and reference numeral 52 denotes a sheet feeding roller that is driven by a motor (not shown). With these configurations, the recording medium is fed to a position facing the discharge port surface of the recording head and is ejected via a paper ejection roller 53 as the recording progresses. In the above-described configuration, when the recording head 65 returns to the home position at the end of the recording, the cap 62 of the discharge recovery portion 64 has been retracted from the movement path of the recording head, but the blade 61 is in a state of protruding into the movement path. As a result, the discharge port surface of the recording head 65 is wiped.

In addition, when the cap 62 abuts on the discharge port surface of the recording head 65 to perform capping, the cap 62 moves to protrude into the movement path of the recording head. In a case where the recording head 65 moves from the home position to a recording start position, the cap 62 and the blade 61 are in the same positions as the above-described positions at the time of wiping. As a result, the discharge surface of the recording head 65 is also wiped during this movement.

The recording head does not only move to the home position as described above at the end of recording or at the time of discharge recovery, but also moves to the home position adjacent to the recording region at predetermined intervals while the recording head moves in the recording region for recording, and the wiping is performed along with these movements.

In the inkjet recording device, color recording can be performed using a recording head in which discharge ports for cyan, magenta, yellow, and black are arranged in parallel in one head. In addition, recording heads for individual colors may be independently arranged in parallel and used. In these cases, individual colors may be discharged from one discharge port, or individual colors may be discharged from a plurality of discharge ports at the same time such that two or more liquid drops of the color are attached to a recording medium at the same time.

In the liquid discharge head, the surface treatment is performed with the photosensitive epoxy resin, which is an ink-repellent treatment material having the material configuration described above, and it is thus possible to maintain the nozzle surface in the same surface state at all times. As a result, even when the liquid discharge head has been in contact with a recording liquid for a long period of time, only a small amount of inkjet ink is attached thereto, and the attached ink is extremely easily removed with a cleaning wiper blade. Accordingly, the substantial persistence of printing becomes remarkably high, and the printing quality can be relentlessly maintained for a long period of time.

### EXAMPLES

Hereinafter, the present disclosure will be described based on Examples, but the present invention is not limited to these Examples. In the following text of the Examples, the number of parts is on a mass basis unless specifically indicated otherwise.

Components used in each of the following Examples and Comparative Examples are shown in Tables 1 to 3 below. As (B) a cationic polymerization catalyst, CPS-410S (trade name, manufactured by San-Apro Ltd.) was used in all of the Examples and the Comparative Examples.

TABLE 1

| | | Number of |
|---|---|---|
| (A) Epoxy resin | | functional groups |
| A-1 | EHPE-3150 (Trade name, Daicel Corporation) | Trifunctional |
| A-2 | 157S70 (Trade name, Mitsubishi Chemical Corporation) | Trifunctional |
| A-3 | jER1004 (Trade name, Mitsubishi Chemical Corporation) | Difunctional |

In Table 1, the number of functional groups indicates the number of epoxy groups in one molecule of the epoxy resin.

TABLE 2

| | | | Functional |
|---|---|---|---|
| | | | group |
| (C) Silicone compound | | Modification | equivalent |
| C-1 | X-22-163 (Trade name, Shin-Etsu Chemical Co., Ltd.) | Both-terminal type | 200 |
| C-2 | KF-105 (Trade name, Shin-Etsu Chemical Co., Ltd.) | Both-terminal type | 490 |
| C-3 | X-22-163A (Trade name, Shin-Etsu Chemical Co., Ltd.) | Both-terminal type | 1000 |
| C-4 | X-22-163B (Trade name, Shin-Etsu Chemical Co., Ltd.) | Both-terminal type | 1800 |
| C-5 | X-22-163C (Trade name, Shin-Etsu Chemical Co., Ltd.) | Both-terminal type | 2700 |
| C-6 | X-22-173BX (Trade name, Shin-Etsu Chemical Co., Ltd.) | Single-terminal type | 2500 |
| C-7 | X-22-173DX (Trade name, Shin-Etsu Chemical Co., Ltd.) | Single-terminal type | 4600 |
| C-8 | X-22-243 (Trade name, Shin-Etsu Chemical Co., Ltd.) | Side-chain type | 525 |
| C-9 | KF-101 (Trade name, Shin-Etsu Chemical Co., Ltd.) | Side-chain type | 350 |
| C-10 | KF-1001 (Trade name, Shin-Etsu Chemical Co., Ltd.) | Side-chain type | 3500 |

In Table 2, “modification” indicates the type of modification of the epoxy-modified silicone. The functional group equivalent represents the epoxy group functional group equivalent.

TABLE 3

| | |
|---|---|
| (D) Alcohol or phenol compound | Number of carbon atoms |

| | | |
|---|---|---|
| D-1 | 1-Nonanol | C9 |
| D-2 | Lauryl alcohol | C12 |
| D-3 | Myristyl alcohol | C14 |
| D-4 | Cetanol | C16 |
| D-5 | Stearyl alcohol | C18 |
| D-6 | Dodecylphenol | C12 |
| D-7 | 1-Octanol | C8 |
| D-8 | Arachidyl alcohol | C20 |

In Table 3, the number of carbon atoms indicates the number of carbon atoms in an alkyl group of an alcohol or phenol compound.

### Examples 1 to 49

Photosensitive epoxy resin compositions 1 to 49 shown in Table 4 were dissolved in PGMEA solvents to produce 30 mass % solutions.

The obtained photosensitive epoxy resin solutions were applied in a thickness of 1 μm in a wet manner using a spinner onto silicon wafer substrates having a 5 μm-thick thermal oxide film. These substrates were then dried on a hot plate at 110° C. for five minutes to remove solvents.

The surfaces of the substrates after the removal of the solvents were irradiated with ultraviolet rays at an integrated amount of 2 J/cm² through masks using a high-pressure mercury lamp in an ultraviolet irradiation device. After that, the surfaces were developed using methyl isobutyl ketone (MIBK) to form 100 cylindrical patterns. The substrates on which the patterns had been formed were heated in a furnace at 200° C. for one hour to complete curing reactions.

The following evaluations were performed using the substrates produced by the above-described method.

### Patterning Properties

The patterns of a cured product on the substrate were observed with a microscope (metal microscope).

All of the cylindrical shapes of the formed 100 patterns were observed, and the patterning properties were evaluated as “A” in a case where the number of cylindrical shapes patterned with no problems was 90 or more, “B” in the case of 80 or more and less than 90, “C” in the case of 70 or more and less than 80, and “D” in the case of less than 70. Meanwhile, in a case where the shapes were cylindrical and did not collapse, the surface was determined to be patterned with no problems. The evaluation results of the patterning properties are shown in Tables 4 and 5.

### Initial Water Repellency

The static contact angle of pure water on the substrate on which the above-described cylindrical patterns had been formed was measured under a normal temperature environment.

As the static contact angle, the contact angle was measured when pure water was dropped onto the substrate on which the above-described cylindrical patterns had been formed.

The initial water repellency was evaluated from the value of the measured static contact angle according to the following criteria. That is, the initial water repellency was evaluated as “A” in a case where the static contact angle was 100 degrees or more, “B” in the case of 90 degrees or more and less than 100 degrees, “C” in the case of 80 degrees or more and less than 90 degrees, “C′” in the case of 75 degrees or more and less than 80 degrees, and “D” in the case of less than 75 degrees.

The evaluation results of the initial water repellency are shown in Tables 4 and 5.

TABLE 4

| Example No. | | | 1 | 2 | 3 | 4 | 5 | 6 | 7 | 8 | 9 | 10 | 11 | 12 | 13 | 14 |
|---|---|---|---|---|---|---|---|---|---|---|---|---|---|---|---|---|
| Amount | (A) Epoxy | A-1 | 100 | 100 | 100 | 100 | 100 | 100 | 100 | 100 | 100 | 100 | 100 | 100 | 100 | 100 |
| added | resin | A-2 | — | — | — | — | — | — | — | — | — | — | — | — | — | — |
| (parts by | | A-3 | — | — | — | — | — | — | — | — | — | — | — | — | — | — |
| mass) | (B) Cationic | | 8 | 8 | 8 | 8 | 8 | 8 | 8 | 8 | 8 | 8 | 8 | 8 | 8 | 8 |
| | polymerization | | | | | | | | | | | | | | | |
| | catalyst | | | | | | | | | | | | | | | |
| | (C) Silicone | C-1 | — | 0.8 | — | — | — | — | — | — | — | — | 0.4 | 0.5 | 10 | 12 |
| | compound | C-2 | — | — | 0.8 | — | — | — | — | — | — | — | — | — | — | — |
| | | C-3 | 0.8 | — | — | — | — | — | — | — | — | — | — | — | — | — |
| | | C-4 | — | — | — | 0.8 | — | — | — | — | — | — | — | — | — | — |
| | | C-5 | — | — | — | — | 0.8 | — | — | — | — | — | — | — | — | — |
| | | C-6 | — | — | — | — | — | 0.8 | — | — | — | — | — | — | — | — |
| | | C-7 | — | — | — | — | — | — | 0.8 | — | — | — | — | — | — | — |
| | | C-8 | — | — | — | — | — | — | — | 0.8 | — | — | — | — | — | — |
| | | C-9 | — | — | — | — | — | — | — | — | 0.8 | — | — | — | — | — |
| | | C-10 | — | — | — | — | — | — | — | — | — | 0.8 | — | — | — | — |
| | (D) Alcohol | D-1 | — | — | — | — | — | — | — | — | — | — | — | — | — | — |
| | or phenol | D-2 | 20 | 20 | 20 | 20 | 20 | 20 | 20 | 20 | 20 | 20 | 20 | 20 | 20 | 20 |
| | compound | D-3 | — | — | — | — | — | — | — | — | — | — | — | — | — | — |
| | | D-4 | — | — | — | — | — | — | — | — | — | — | — | — | — | — |
| | | D-5 | — | — | — | — | — | — | — | — | — | — | — | — | — | — |
| | | D-6 | — | — | — | — | — | — | — | — | — | — | — | — | — | — |

| | | | | | | | | | | | | | | | |
|---|---|---|---|---|---|---|---|---|---|---|---|---|---|---|---|
| Evaluation | Patterning properties | A | A | A | A | B | A | A | A | A | A | B | A | A | A |
| | Initial water repellency | A | B | A | A | A | C | C | C | C | C | B | B | B | C |

| Example No. | | | 15 | 16 | 17 | 18 | 19 | 20 | 21 | 22 | 23 | 24 | 25 | 26 |
|---|---|---|---|---|---|---|---|---|---|---|---|---|---|---|
| Amount | (A) Epoxy | A-1 | 100 | 100 | 100 | 100 | 100 | 100 | 100 | 100 | 100 | 100 | 100 | 100 |
| added | resin | A-2 | — | — | — | — | — | — | — | — | — | — | — | — |
| (parts by | | A-3 | — | — | — | — | — | — | — | — | — | — | — | — |
| mass) | (B) Cationic | | 8 | 8 | 8 | 8 | 8 | 8 | 8 | 8 | 8 | 8 | 8 | 8 |
| | polymerization | | | | | | | | | | | | | |
| | catalyst | | | | | | | | | | | | | |
| | (C) Silicone | C-1 | — | — | — | — | — | — | — | — | — | — | — | — |
| | compound | C-2 | — | — | — | — | — | — | — | — | — | — | — | — |
| | | C-3 | 0.4 | 0.5 | 10 | 12 | — | — | — | — | — | — | — | — |
| | | C-4 | — | — | — | — | — | — | — | — | — | — | — | — |
| | | C-5 | — | — | — | — | — | — | — | — | — | — | — | — |
| | | C-6 | — | — | — | — | 0.4 | 0.5 | 10 | 12 | — | — | — | — |
| | | C-7 | — | — | — | — | — | — | — | — | — | — | — | — |
| | | C-8 | — | — | — | — | — | — | — | — | 0.4 | 0.5 | 10 | 12 |
| | | C-9 | — | — | — | — | — | — | — | — | — | — | — | — |
| | | C-10 | — | — | — | — | — | — | — | — | — | — | — | — |
| | (D) Alcohol | D-1 | — | — | — | — | — | — | — | — | — | — | — | — |
| | or phenol | D-2 | 20 | 20 | 20 | 20 | 20 | 20 | 20 | 20 | 20 | 20 | 20 | 20 |
| | compound | D-3 | — | — | — | — | — | — | — | — | — | — | — | — |
| | | D-4 | — | — | — | — | — | — | — | — | — | — | — | — |
| | | D-5 | — | — | — | — | — | — | — | — | — | — | — | — |
| | | D-6 | — | — | — | — | — | — | — | — | — | — | — | — |

| | | | | | | | | | | | | | |
|---|---|---|---|---|---|---|---|---|---|---|---|---|---|
| Evaluation | Patterning properties | A | A | A | B | A | A | A | B | A | A | A | B |
| | Initial water repellency | B | A | A | A | C | B | B | C | C | B | B | C |

TABLE 5

| Example No. | | | 27 | 28 | 29 | 30 | 31 | 32 | 33 | 34 | 35 | 36 | 37 | 38 |
|---|---|---|---|---|---|---|---|---|---|---|---|---|---|---|
| Amount | (A) Epoxy | A-1 | — | — | — | — | — | — | 100 | 100 | 100 | 100 | 100 | 100 |
| added | resin | A-2 | 100 | 100 | 100 | 100 | 100 | — | — | — | — | — | — | — |
| (parts by | | A-3 | — | — | — | — | — | 100 | — | — | — | — | — | — |
| mass) | (B) Cationic | | 8 | 8 | 8 | 8 | 8 | 8 | 8 | 8 | 8 | 8 | 8 | 8 |
| | polymerization catalyst | | | | | | | | | | | | | |
| | (C) Silicone | C-1 | — | — | 0.8 | — | — | — | — | — | — | — | — | — |
| | compound | C-2 | — | — | — | — | — | — | — | — | — | — | — | — |
| | | C-3 | 0.8 | 0.8 | — | — | — | — | 0.8 | 0.8 | 0.8 | 0.8 | 0.8 | 0.8 |
| | | C-4 | — | — | — | — | — | — | — | — | — | — | — | — |
| | | C-5 | — | — | — | — | — | 0.8 | — | — | — | — | — | — |
| | | C-6 | — | — | — | 0.8 | — | — | — | — | — | — | — | — |
| | | C-7 | — | — | — | — | — | — | — | — | — | — | — | — |
| | | C-8 | — | — | — | — | — | — | — | — | — | — | — | — |
| | | C-9 | — | — | — | — | 0.8 | — | — | — | — | — | — | — |
| | | C-10 | — | — | — | — | — | — | — | — | — | — | — | — |
| | (D) Alcohol | D-1 | — | — | — | — | — | — | 20 | — | — | — | — | 9 |
| | or phenol | D-2 | 20 | 30 | 30 | 30 | 30 | 20 | — | — | — | — | — | — |
| | compound | D-3 | — | — | — | — | — | — | — | 20 | — | — | — | — |
| | | D-4 | — | — | — | — | — | — | — | — | 20 | — | — | — |
| | | D-5 | — | — | — | — | — | — | — | — | — | 20 | — | — |
| | | D-6 | — | — | — | — | — | — | — | — | — | — | 20 | — |

| | | | | | | | | | | | | | |
|---|---|---|---|---|---|---|---|---|---|---|---|---|---|
| Evaluation | Patternin gproperties | C | B | B | B | B | C | B | A | A | A | A | C |
| | Initial water repellency | A | A | A | A | A | B | A | A | A | B | B | B |

| Example No. | | | 39 | 40 | 41 | 42 | 43 | 44 | 45 | 46 | 47 | 48 | 49 |
|---|---|---|---|---|---|---|---|---|---|---|---|---|---|
| Amount | (A) Epoxy | A-1 | 100 | 100 | 100 | 100 | 100 | 100 | 100 | 100 | 100 | 100 | 100 |
| added | resin | A-2 | — | — | — | — | — | — | — | — | — | — | — |
| (parts by | | A-3 | — | — | — | — | — | — | — | — | — | — | — |
| mass) | (B) Cationic | | 8 | 8 | 8 | 8 | 8 | 8 | 8 | 8 | 8 | 8 | 8 |
| | polymerization catalyst | | | | | | | | | | | | |
| | (C) Silicone | C-1 | — | — | — | — | — | — | — | — | — | — | — |
| | compound | C-2 | — | — | — | — | — | — | — | — | — | — | — |
| | | C-3 | 0.8 | 0.8 | 0.8 | 0.8 | 0.8 | 0.8 | 0.8 | 0.8 | 0.8 | 0.8 | 0.8 |
| | | C-4 | — | — | — | — | — | — | — | — | — | — | — |
| | | C-5 | — | — | — | — | — | — | — | — | — | — | — |
| | | C-6 | — | — | — | — | — | — | — | — | — | — | — |
| | | C-7 | — | — | — | — | — | — | — | — | — | — | — |
| | | C-8 | — | — | — | — | — | — | — | — | — | — | — |
| | | C-9 | — | — | — | — | — | — | — | — | — | — | — |
| | | C-10 | — | — | — | — | — | — | — | — | — | — | — |
| | (D) Alcohol | D-1 | 10 | 40 | 41 | — | — | — | — | — | — | — | — |
| | or phenol | D-2 | — | — | — | 9 | 10 | 40 | 41 | — | — | — | — |
| | compound | D-3 | — | — | — | — | — | — | — | — | — | — | — |
| | | D-4 | — | — | — | — | — | — | — | — | — | — | — |
| | | D-5 | — | — | — | — | — | — | — | 9 | 10 | 40 | 41 |
| | | D-6 | — | — | — | — | — | — | — | — | — | — | — |

| | | | | | | | | | | | | |
|---|---|---|---|---|---|---|---|---|---|---|---|---|
| Evaluation | Patternin gproperties | B | B | C | B | A | A | B | B | A | A | B |
| | Initial water repellency | A | A | A | B | A | A | A | C | B | B | B |

In the compositions of Examples 1 to 4, 6 to 10, 12 to 17, 19 to 21, 23 to 25, 34 to 37, 43, 44, 47, and 48, particularly excellent patterning properties were shown. In addition, in the compositions of Examples 1, 3 to 5, 16 to 18, 27 to 32, 33 to 35, 39 to 41, and 43 to 45, favorable results were obtained in terms of the initial water repellency, and in the compositions of Examples 1, 3, 4, 16, 17, 34, 35, 43, and 44, both the patterning properties and the initial water repellency were excellent.

The individual results are analyzed as described below.

Examples 1 to 10 showed the results of compositions in which a variety of silicone compounds (both-terminal epoxy-modified, single-terminal epoxy-modified, side-chain epoxy-modified) were used as a component (C) as shown in Table 1 and 0.8 parts by mass of the component (C) was added to 100 parts by mass of the epoxy resin that was a component (A).

Examples 1 to 5 where both-terminal epoxy-modified silicones were used had superior initial water repellency. This can be believed to be because introduction of epoxy groups into both ends of the molecule of the silicone compound made it possible to efficiently orient water-repellent groups (methyl groups) on the surface compared with side chain type modification, the water-repellent group on the outermost surface of the cured product was unlikely to rotate internally compared with single terminal type, and the like.

Furthermore, Examples 1, 3, and 4 where, among the both-terminal epoxy-modified silicone compounds, silicone compounds having an epoxy group functional group equivalent of from 490 to 1800 were used showed the most favorable results. Examples 1, 3 and 4 had superior initial water repellency to Example 2 where the functional group equivalent was 200. This is assumed to be because the silicone compound used in Example 2 had an epoxy group at an end having a high reactivity and there was a tendency that water-repellent groups were unlikely to be oriented on the surface during curing.

In addition, Examples 1 to 4 had superior patterning properties to Example 5 where the functional group equivalent was 2,700. This is believed to be because the silicone compound used in Example 5 had a relatively long silicone structure in the main chain and was likely to aggregate in the epoxy resin.

Examples 11 to 26 showed the results of compositions in which the types of the silicone compounds as the component (C) and the amounts added to 100 parts by mass of the epoxy resin were changed as shown in Table 1. In all of the silicone compounds, in a case where the amount of the silicone compound added to 100 parts by mass of the epoxy resin was 0.5 parts by mass or more and 10 parts by mass or less, the patterning properties and the initial water repellency were particularly favorable.

Examples 12, 16, 20, and 24 where the amounts of the silicone compounds added were 0.5 parts by mass had superior initial water repellency to Examples 11, 15, 19, and 23. It is believed to be because the water-repellent groups were sufficiently comprised in the photosensitive epoxy resin composition. On the other hand, Examples 13, 17, 21 and 25 where the amounts of the silicone compounds added were 10 parts by mass had superior patterning properties to Examples 14, 18, 22 and 26.

Examples 27 to 32 showed the results of compositions in which trifunctional or bifunctional epoxy resins were used as the component (A) as shown in Table 1. Examples 1 and 27 to 31 where tri-functional epoxy resins were used showed superior patterning properties to Example 32 where a bifunctional epoxy resin was used. In addition, among the Examples where tri-functional epoxy resins were used, in Example 27, there was a tendency that the patterning properties were slightly low, which is assumed to be because the compatibility with the component (C) was poor. However, excellent patterning properties could be obtained by adding a large amount of a compatibilizer as the component (D) as in Examples 28 to 31.

Examples 33 to 37 showed the results of compositions in which alcohols or phenol compounds comprising a long chain alkyl group having 9 to 18 carbon atoms were used as the component (D) as shown in Table 1. In Examples 1, 34, 35, and 36 where lauryl alcohol, myristyl alcohol, or cetanol having 12 to 16 carbon atoms was used, the most favorable results were shown in terms of the patterning properties and the initial water repellency.

Examples 34 to 36 where the numbers of carbon atoms in alkyl groups were 12 or more had superior patterning properties to Example 33 where the number of carbon atoms was nine. It is believed that as the number of carbon atoms in the alkyl group increases, the boiling point increases, and the component (D) is more unlikely to volatilize during baking, and superior patterning properties can be thus obtained.

Incidentally, Examples 33 to 35 where the numbers of carbon atoms in alkyl groups were 16 or less had superior initial water repellency to Example 36 where the number of carbon atoms was 18. It is believed that in the components (D) used in Examples 33 to 35, the chain lengths of the alkyl groups were excessively long, and the effects as compatibilizers were sufficiently exhibited. In Example 37, a phenol compound was used, but the initial water repellency was superior to those in Examples 33 to 35 where alcohol compounds were used.

In Examples 38 to 49, compositions in which the types of components (D) and the amounts added to 100 parts by mass of the epoxy resin were changed as shown in Table 1 were used. In all cases where the compounds were used, the most favorable results were shown in a case where the amount added was 10 parts by mass or more and 40 parts by mass or less.

Examples 39, 43, and 47 where the amounts of the components (D) added were 10 parts by mass were superior in terms of the patterning properties and the initial water repellency to Examples 38, 42, and 46 where the amounts added were less than 10 parts by mass. This is because the compatibilizers appropriately worked and no segregation occurred in the epoxy resins or the silicone compounds.

In addition, Examples 40, 44, and 48 where the amounts of the component (D) added were 40 parts by mass had superior patterning properties to Examples 41, 45, and 49 where the amounts added exceeded 40 parts by mass.

In a case where the amount of the component (D) added is large, the compatibility improves, but the proportion of the component (D) remaining in the cured product after the baking also increases. Therefore, it is believed that when the amount of the component (D) added is set to 40 parts by mass or less, it becomes easy to further improve the patterning properties.

Subsequently, an inkjet recording head was produced by the following procedure.

### Production of Inkjet Recording Head

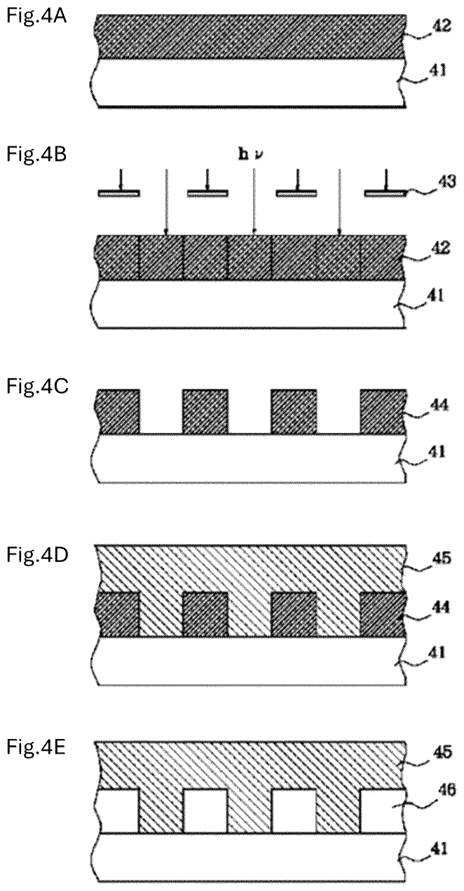

As shown in FIG. 4A, a positive type photo resist 42 (“PMER AR-900” manufactured by Tokyo Ohka Kogyo Co., Ltd.) was spin-coated on a base material 41 provided with a discharge energy generating element or the like in advance such that the film thickness reached 30 μm. After that, the photo resist was prebaked in an oven at 90° C. for 40 minutes to form a resist layer.

The formed resist layer was patterned using a mask 43 to obtain a resist pattern 44 as shown in FIGS. 4B and 4C. Reference sign hv in FIG. 4B denotes an active energy ray. As a flow path-forming material, a curing agent (modified aliphatic amine, “FUJICURE FXK 830” manufactured by Fuji Kasei Co., Ltd.) was mixed with “EPICLON N-695” manufactured by DIC Corporation at a main agent/curing agent ratio of 100/50 (weight ratio) and laminated on the resist pattern 44 in a layer thickness of 100 μm as shown in FIG. 4D, thereby forming a flow path-forming material layer 45.

After the flow path-forming material layer 45 was laminated and then left to stand at 25° C. for 24 hours, furthermore, a heat curing treatment was performed at 100° C. for two hours, thereby obtaining a laminate. Next, the obtained laminate was immersed in a 3 weight % sodium hydroxide aqueous solution to dissolve and remove the resist pattern 44. The laminate after the dissolution and removal was washed and dried to form liquid flow paths 46 (FIG. 4E), and an inkjet recording head, which is a liquid discharge head, was obtained.

### Surface Treatment of Liquid Discharge Surface

The photosensitive epoxy resin composition of Example 1 was applied to a discharge surface (a surface on which discharge ports had been formed) of the obtained inkjet recording head and cured by exposure to ultraviolet rays at 8 J/cm² and one-hour heating at 200° C. to perform a surface treatment. Furthermore, predetermined electrical wiring was performed on the surface-treated inkjet recording head, the inkjet recording head was incorporated into a printer, and the following long-term printing durability test was performed using an inkjet ink composed of pure water/glycerin/hood black 2 (water-soluble black dye)/N-methylpyrrolidone=70/15/3/12 (parts by weight). The photosensitive epoxy resin compositions of Examples 2 to 49 were also applied to the discharge surfaces by the same method as in Example 1, and long-term printing durability tests were performed.

### Printing Durability Test

In the printing durability test, 100 sheets of patterns for evaluating documents and landing accuracy were printed, and dot distortion was evaluated from the final printing sample.

The dot distortion was measured by the following method. The 100th printing sample was observed with a microscope, and the proportion of the number of dots off the center (dot position distortion) in the total number of dots was calculated. The calculated values were evaluated according to the following criteria:
Evaluation A: The dot position distortion is less than 3%, and characters are clear.
Evaluation B: The dot position distortion is 3% or more and less than 10%, and the influence on the character quality is slight.
Evaluation C: The dot position distortion is 10% or more and less than 50%, and the clarity of characters has also deteriorated.
Evaluation D: The dot position distortion is 50% or more, and the character quality significantly deteriorates.

The evaluation results are shown in Table 6. In the Examples where favorable results were obtained in terms of both the patterning properties and the initial water repellency, high evaluation results were also shown in the printing durability tests.

TABLE 6

| | Printing durability |
|---|---|
| Example | test result |
| 1 | A |
| 2 | B |
| 3 | A |
| 4 | A |
| 5 | C |
| 6 | C |
| 7 | C |
| 8 | C |
| 9 | C |
| 10 | C |
| 11 | B |
| 12 | B |
| 13 | B |
| 14 | B |
| 15 | B |
| 16 | A |
| 17 | A |
| 18 | B |
| 19 | B |
| 20 | B |
| 21 | B |
| 22 | C |
| 23 | B |
| 24 | B |
| 25 | B |
| 26 | C |
| 27 | C |
| 28 | B |
| 29 | B |
| 30 | B |
| 31 | B |
| 32 | C |
| 33 | B |
| 34 | A |
| 35 | A |
| 36 | A |
| 37 | A |
| 38 | C |
| 39 | B |
| 40 | B |
| 41 | C |
| 42 | B |
| 43 | A |
| 44 | A |
| 45 | B |
| 46 | C |
| 47 | A |
| 48 | A |
| 49 | B |

### Comparative Examples 1 and 2

Table 7 shows the compositions of resin compositions of the Comparative Examples and the evaluation results of the patterning properties and the initial water repellency by the same procedure as in the Examples.

In Comparative Example 1, 1-octanol having eight carbon atoms was added as the component (D), but the patterning properties was poor compared with those in the Examples. This is believed to be because the volatilization rate of the component (D) was faster than the curing of the resin and the compatibility of the cured product deteriorated.

In Comparative Example 2, arachidyl alcohol having 20 carbon atoms was added as the component (D), but the initial water repellency was poor compared with those in the Examples. It is believed to be because the hydrophobic alkyl group was a long chain, the balance with a hydrophilic hydroxyl group collapsed, and the effect as a compatibilizer could not be obtained.

In addition, surface treatments were performed on the discharge surfaces of the inkjet recording heads by the same method as in the Examples using the resin compositions of Comparative Examples 1 and 2. The results of the printing durability tests performed on the obtained inkjet recording heads by the same procedure as in the Examples are shown in Table 8. In both cases, the evaluation results were D.

TABLE 7

| Example No. | | | 1 | 2 |
|---|---|---|---|---|
| Amount | (A) Epoxy resin | A-1 | 100 | 100 |
| added | (B) Cationic polymerization catalyst | | 8 | 8 |
| (parts by | (C) Silicone compound | C-1 | 0.8 | 0.8 |
| mass) | (D) Alcohol or phenol | D-7 | 20 | — |
| | compound | D-8 | — | 20 |

| | | | |
|---|---|---|---|
| Evaluation | Patterning properties | D | A |
| | Initial water repellency | A | D |

TABLE 8

| Comparative | Printing durability |
|---|---|
| Example | test result |
| 1 | D |
| 2 | D |

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions. This application claims the benefit of Japanese Patent Application No. 2024-071585, filed Apr. 25, 2024, and Japanese Patent Application No. 2025-066318 filed Apr. 14, 2025, which are hereby incorporated by reference herein in their entirety.

What is claimed is:

1. A photosensitive epoxy resin composition, comprising at least:
(A) an epoxy resin comprising two or more epoxy groups in one molecule;
(B) a cationic polymerization catalyst;
(C) a silicone compound comprising one or more alkylsiloxane groups in one molecule; and
(D) an alcohol or phenol compound comprising a long chain alkyl group having 9 to 18 carbon atoms.

2. The photosensitive epoxy resin composition according to claim 1, wherein the silicone compound is a both-terminal epoxy-modified silicone compound in which both ends of one molecule are modified to epoxy groups.

3. The photosensitive epoxy resin composition according to claim 2, wherein the both-terminal epoxy-modified silicone compound has an epoxy group functional group equivalent of 150 or more and 3000 or less.

4. The photosensitive epoxy resin composition according to claim 1, wherein a content of the silicone compound relative to 100 parts by mass of the epoxy resin is 0.5 parts by mass or more and 10 parts by mass or less.

5. The photosensitive epoxy resin composition according to claim 1, wherein the epoxy resin comprises an epoxy resin comprising a tri- or higher-functional epoxy group in one molecule.

6. The photosensitive epoxy resin composition according to claim 1, wherein the alcohol or phenol compound is at least one selected from the group consisting of lauryl alcohol, myristyl alcohol, and cetanol.

7. The photosensitive epoxy resin composition according to claim 1, wherein a total content of the alcohol or the phenol compound relative to 100 parts by mass of the epoxy resin is 10 parts by mass or more and 50 parts by mass or less.

8. A surface treatment method comprising in order:
a first step of applying a photosensitive epoxy resin composition to a base material, and drying the photosensitive epoxy resin composition to form a coating film;
a second step of irradiating a surface of the base material, on which the coating film has been formed, with an active energy ray in a pattern through a mask; and
a third step of dissolving and removing an uncured photosensitive epoxy resin composition present in a part not irradiated with the active energy ray,
wherein the photosensitive epoxy resin composition comprises at least
(A) an epoxy resin comprising two or more epoxy groups in one molecule,
(B) a cationic polymerization catalyst,
(C) a silicone compound comprising one or more alkylsiloxane groups in one molecule, and
(D) an alcohol or phenol compound comprising a long chain alkyl group having 9 to 18 carbon atoms.

9. The surface treatment method according to claim 8, further comprising:
a fourth step of performing heat treatment or irradiation with an active energy ray after the third step.

10. A surface treatment method comprising in order:
a first step of applying a photosensitive epoxy resin composition on a base material, and drying the photosensitive epoxy resin composition to form a coating film;
a second step of performing a heat treatment or irradiation with an active energy ray on an entire surface of the base material, on which the coating film has been formed, and polymerizing and curing the photosensitive epoxy resin composition to obtain a cured product; and
a third step of selectively irradiating the cured product with a collapsible active energy ray to mold the cured product into a pattern,
wherein the photosensitive epoxy resin composition comprises at least
(A) an epoxy resin comprising two or more epoxy groups in one molecule,
(B) a cationic polymerization catalyst,
(C) a silicone compound comprising one or more alkylsiloxane groups in one molecule, and
(D) an alcohol or a phenol compound comprising a long chain alkyl group having 9 to 18 carbon atoms.

11. The surface treatment method according to claim 10, further comprising:
a fourth step of performing heat treatment or irradiation with an active energy ray after the second step or the third step.

12. A method for manufacturing a liquid discharge head, comprising:
a step of applying the photosensitive epoxy resin composition according to claim 1 to a surface of a face of a liquid discharge head having a discharge port where the discharge port has been formed; and
a step of curing the photosensitive epoxy resin composition by exposure and a heating treatment.

13. A method for manufacturing a liquid discharge head, comprising:
a step of performing the surface treatment method according to claim 8,
wherein the base material is a base material provided with a discharge energy generating element of the liquid discharge head.

14. A liquid discharge head, comprising:
a discharge port that discharges a recording liquid,
wherein at least an opening portion of the discharge port is coated with a cured product of the photosensitive epoxy resin composition according to claim 1.

15. A liquid discharge device, comprising:
the liquid discharge head according to claim 14.
